(19) United States
(12) Patent Application Publication
(10) Pub. No.: US 2025/0198544 A1
(43) Pub. Date: Jun. 19, 2025

(54) ANTI-OXIDIZED METAL PIPE AND METHOD OF FABRICATING THE SAME

(71) Applicant: METAL INDUSTRIES RESEARCH & DEVELOPMENT CENTRE, KAOHSIUNG (TW)

(72) Inventors: Jia-Hao LIN, Hualien County (TW); Wei-Chen TIEN, Chiayi City (TW); Chang-Sin YE, Tainan City (TW); Chun-Kai HUANG, Kaohsiung City (TW); Ping-Tun HUANG, Changhua County (TW)

(21) Appl. No.: 18/543,624

(22) Filed: Dec. 18, 2023

(51) Int. Cl. F16L 9/147; C23C 16/02; C23C 16/04; C23C 16/30; F16L 9/02

(52) U.S. Cl. CPC F16L 9/147; C23C 16/02; C23C 16/045; C23C 16/30; F16L 9/02

(57) ABSTRACT

An anti-oxidized metal pipe and a method of fabricating the same are provided. The anti-oxidized metal pipe includes a hollow metal pipe and an anti-oxidized thin film. The hollow metal pipe has an inner diameter in a range of 1.5 mm to 4.5 mm. An inner surface of the hollow metal pipe is blanketly covered by the anti-oxidized thin film, and a degree of crystallinity of the anti-oxidized thin film is not greater than 40%. The anti-oxidized metal pipe has great anti-oxidized property in a highly oxidizing environment.

### BACKGROUND

### Field of Invention

The present invention relates to an anti-oxidized metal and a method of fabricating the same. More particularly, the present invention relates to an anti-oxidized metal pipe and a method of fabricating the same.

### Description of Related Art

Plenty of metal materials may oxidize in oxygen gas or while exposing an oxidizing agent (i.e. in an oxidizing environment), to produce an oxidizing layer on a surface of the metal material. When the metal material is stainless steel, chromium oxide may form on the surface of the stainless steel in the oxidizing environment. According to a kinetic curve of metal oxidization, when the stainless steel surface having a thin chromium oxide layer (and other metal oxide layers) is placed in an environment with low oxidation concentration, the oxidation kinetics exhibits a logarithmic curve, and the probability for continuing the oxidation reaction on the surface is little; on the contrary, if the stainless steel is placed in an environment with high oxidation concentration, the oxidation kinetics may be represented by a linear law, cracks may occur in the chromium oxide layer, exposing the surface of the stainless steel, and the stainless steel surface may oxidize repeatedly.

Thus, in order to decrease or avoid the stainless steel continuing to oxidize in the environment with high oxidation concentration, an anti-oxidized thin film can be formed on the surface of the stainless steel to protect the stainless steel from oxidizing. A more stable material than chromium oxide can be chosen as the anti-oxidized thin film to achieve a better protection effect.

Therefore, it is needed to provide a method of fabricating the anti-oxidized metal pipe to protect the inner surface of the metal pipe from oxidizing in an application process.

### SUMMARY

An aspect of the present invention provides an anti-oxidized metal pipe, which has an anti-oxidized thin film with a low degree of crystallinity or amorphous structure, thereby applying in an environment with high oxidation concentration.

Another aspect of the present invention provides a method of fabricating an anti-oxidized metal pipe, which forms an anti-oxidized thin film with a low degree of crystallinity or amorphous structure on an inner surface of a hollow metal pipe by a low-pressure chemical vapor deposition process.

According to the aspect of the present invention, the anti-oxidized metal pipe is provided. The anti-oxidized metal pipe includes a hollow metal pipe and an anti-oxidized thin film. The hollow metal pipe has an inner diameter between 1.0 mm to 4.5 mm. The anti-oxidized thin film blanketly covers an inner surface of the hollow metal pipe, and the anti-oxidized thin film has a degree of crystallinity not greater than 40%.

According to an embodiment of the present invention, a material of the hollow metal pipe includes stainless steel, aluminum alloy, copper alloy or combinations thereof.

According to an embodiment of the present invention, a thickness of the anti-oxidized thin film is 50 nm to 1000 nm.

According to an embodiment of the present invention, the anti-oxidized thin film completely and blanketly covers the hollow metal pipe.

According to an embodiment of the present invention, the degree of crystallinity of the anti-oxidized thin film is 1% to 20%.

According to an embodiment of the present invention, the anti-oxidized thin film includes carbon-free hydrogenated amorphous silicon.

According to the another aspect of the present invention, the method of fabricating an anti-oxidized metal pipe is provided. The method includes providing a hollow metal pipe into a process chamber; and performing a low-pressure chemical vapor deposition process in the process chamber to form an anti-oxidized thin film on an inner surface of the hollow metal pipe, in which the anti-oxidized thin film has a degree of crystallinity not greater than 40%.

According to an embodiment of the present invention, the low-pressure chemical vapor deposition process includes heating the process chamber to a reaction temperature, in which the reaction temperature is 420° C. to 600° C.; and introducing a mixing gas comprising silane and hydrogen gas into the process chamber.

According to an embodiment of the present invention, based on a volume of the hydrogen gas as 100 vol %, a volume of the silane is 40 vol % to 60 vol %.

According to an embodiment of the present invention, a pressure of the low-pressure chemical vapor deposition process is 0.1 Torr to 100 Torr.

According to an embodiment of the present invention, before performing the low-pressure chemical vapor deposition process, the method further includes performing an oxidation process to form a metal oxide layer on the inner surface of the hollow metal pipe.

According to an embodiment of the present invention, the anti-oxidized thin film is covalently bonded to the metal oxide layer.

According to an embodiment of the present invention, the hollow metal pipe has an aspect ratio not smaller than 114.

According to an embodiment of the present invention, the hollow metal pipe has an inner diameter between 1.0 mm to 4.5 mm.

According to the aspect of the present invention, the anti-oxidized metal pipe is provided. The anti-oxidized metal pipe includes a hollow metal pipe and an anti-oxidized thin film. The hollow metal pipe has an aspect ratio not smaller than 114. The anti-oxidized thin film blanketly covers an inner surface of the hollow metal pipe, and the anti-oxidized thin film includes an amorphous structure.

According to an embodiment of the present invention, the hollow metal pipe has an inner diameter between 1.0 mm to 4.5 mm.

According to an embodiment of the present invention, the anti-oxidized thin film has a degree of crystallinity not greater than 40%.

According to an embodiment of the present invention, a thickness of the anti-oxidized thin film is 50 nm to 1000 nm.

According to an embodiment of the present invention, the inner surface of the hollow metal pipe includes a metal oxide layer.

According to an embodiment of the present invention, the anti-oxidized thin film includes hydrogenated amorphous silicon, and silicon atoms of the hydrogenated amorphous silicon are covalently bonded to oxygen atoms of the metal oxide layer.

Application of the anti-oxidized metal pipe and the method of fabricating the same, the anti-oxidized thin film is deposited on the inner surface of the hollow metal pipe, and the degree of crystallinity of the anti-oxidized thin film is controlled to ensure that the anti-oxidized metal pipe to have great anti-oxidized property in the environment with high oxidation concentration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of an anti-oxidized metal pipe according to some embodiments of the present invention.

FIG. 2 illustrates a cross-section diagram of a portion of the anti-oxidized metal pipe according to some embodiments of the present invention.

FIG. 3 illustrates Raman spectrum of Embodiment 2 and Comparative example 2 of the present invention.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range.

In general, due to a limitation of shape or size of inner walls, the inner walls of a metal pipe are not convenient to perform a modification treatment. In order to ensure that the metal pipe can be applied in the environment with high oxidation concentration, as stated above, an anti-oxidized metal pipe and the method of fabricating the same are provided in the present invention. By depositing an anti-oxidized thin film on an inner surface of the hollow metal pipe, and a degree of crystallinity of the anti-oxidized thin film is controlled to ensure that the anti-oxidized metal pipe to have a great anti-oxidized property in the environment with high oxidation concentration.

It is understood that “the environment with high oxidation concentration” recited in the present invention means that a concentration of oxygen in the environment is about 70% to 95%, or an environment with an oxidizing ability same as above.

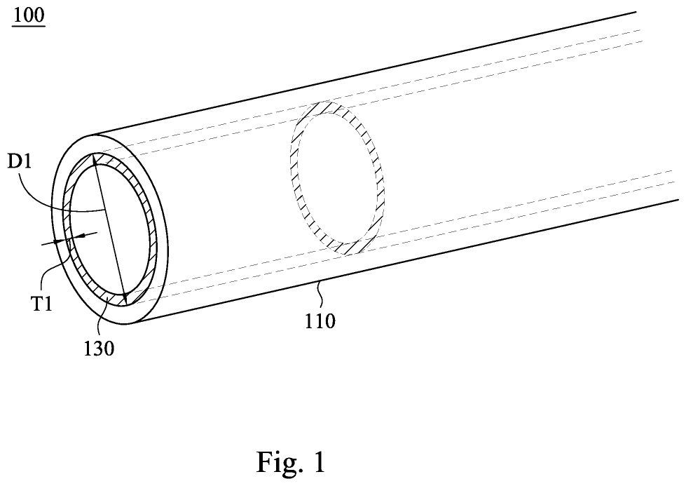

Referring to FIG. 1, FIG. 1 illustrates a schematic diagram of an anti-oxidized metal pipe 100 according to some embodiments of the present invention. The anti-oxidized metal pipe 100 includes a hollow metal pipe 110 and an anti-oxidized thin film 130. The anti-oxidized thin film 130 blanketly covers on an inner surface of the hollow metal pipe 110. In some embodiments, the hollow metal pipe 110 can also optionally have the anti-oxidized thin film on an outer surface, which is not illustrated in FIG. 1. That is, the anti-oxidized thin film 130 can completely and blanketly cover the hollow metal pipe 110.

In some embodiments, an inner diameter D1 of the hollow metal pipe 110 is about 1.0 mm to about 4.5 mm. If the inner diameter D1 of the hollow metal pipe 110 is too small, it will be not advantageous for following application; on the contrary, if the inner diameter D1 of the hollow metal pipe 110 is too great, it will be hard to form a uniform anti-oxidized thin film. In some examples, the hollow metal pipe 110 includes an eighth inch pipe, a quarter inch pipe or combination thereof. In some embodiments, the hollow metal pipe 110 has an aspect ratio (i.e. the ratio of a length to an inner diameter of the hollow metal pipe 110) not smaller than 114. Three-dimensional structures of the hollow metal pipe 110 can be an irregular shape or a regular shape.

In some embodiments, the anti-oxidized thin film 130 has a thickness T1 between about 50 nm and about 1000 nm. The anti-oxidized thin film 130 with the aforementioned thickness range can have better anti-oxidation property and a better homogeneity.

In some embodiments, a material of the hollow metal pipe 110 includes stainless steel, aluminum alloy, copper alloy or combinations thereof. Although the stainless steel pipe is hard to be oxidized to be resulted in cracked in an environment with low oxidation concentration, cracks may occur in the chromium oxide layer on a surface of the stainless steel pipe if it is applied in an environment with high oxidation concentration, and thus the pipe can be oxidized continuously and broken. Therefore, if it is desired to apply the hollow metal pipe in the environment with high oxidation concentration, it is necessary to form the anti-oxidized thin film on its surface for expending its lifetime.

In some embodiments, the anti-oxidized thin film 130 has a degree of crystallinity not greater than about 40%, preferably about 1% to about 20%. If the degree of crystallinity of the anti-oxidized thin film 130 is too great, anti-oxidation effect will be poor. In an example, the anti-oxidized thin film 130 has an amorphous structure. In some embodiments, the anti-oxidized thin film 130 includes carbon-free hydrogenated amorphous silicon. Since the anti-oxidized thin film 130 is carbon-free, it can have better anti-oxidation property. When the anti-oxidized metal pipe 100 has the anti-oxidized thin film 130 with the aforementioned degree of crystallinity, it shows better anti-oxidation property. Raman characteristic peak of the anti-oxidized thin film 130 is between 480 cm⁻¹ to 500 cm⁻¹, indicating that the anti-oxidized thin film 130 mainly has the amorphous structure.

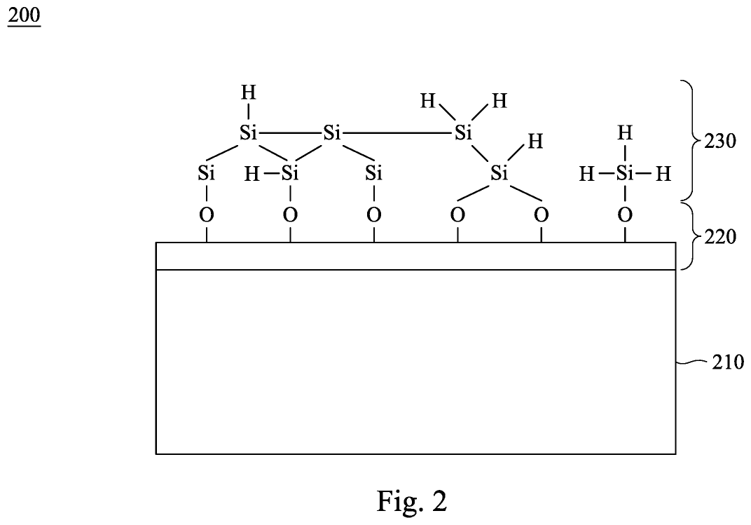

Referring to FIG. 2, FIG. 2 illustrates a cross-section diagram of a portion of the anti-oxidized metal pipe 200 according to some embodiments of the present invention. For example, when the hollow metal pipe 210 includes stainless steel, a metal oxide layer 220 can be formed on the surface of the hollow metal pipe 210 due to the oxidation environment, in which the metal oxide layer 220 includes chromium oxide, ferric oxide and etc. In some embodiments, the anti-oxidized thin film 230 includes carbon-free hydrogenated amorphous silicon. As shown in FIG. 2, silicon atoms of the anti-oxidized thin film 230 can be covalently bonded to oxygen atoms of the metal oxide layer 220, and thus the anti-oxidized thin film 230 can bond with the metal oxide layer 220 effectively. It is understood that when the hollow metal pipe 210 includes aluminum alloy or copper alloy, the anti-oxidized thin film 230 produced by the method of the present invention is formed on the surface of the pipe in a manner similar to the aforementioned bonding mechanism (i.e. Si-O bond).

The following describes the method of fabricating the anti-oxidized metal pipe 100 with FIG. 1. First, the hollow metal pipe 110 is placed in a process chamber. In some embodiments, before providing the hollow metal pipe 110 into the process chamber, a pre-cleaning step should be performed first to remove impurities or greasy dirt on its surface. Subsequently, a low-pressure chemical vapor deposition (LPCVD) process is performed to form the anti-oxidized thin film 130 on the inner surface of the hollow metal pipe 110. In some embodiments, a vacuum-pumping step is performed before performing the LPCVD process, such that a pressure of the process chamber is lower than 1.0×10⁻² Torr, such as 6.0×10⁻³ Torr.

In some embodiments of the anti-oxidized thin film 130 including hydrogenated amorphous silicon, the process chamber is heated first to a reaction temperature in the LPCVD process, and then a mixing gas including silane (SiH₄) and hydrogen is introduced into the process chamber to perform chemical vapor deposition. In some embodiments, based on a volume of the hydrogen in the mixing gas as 100 vol %, a volume of the silane is 40 vol % to 60 vol %. The anti-oxidized thin film 130 formed by the aforementioned ratio of the mixing gas can have less defects. In some embodiments, the reaction temperature of the LPCVD process is about 420° C. to about 600° C., preferably about 500° C. to about 600° C. The aforementioned reaction temperature helps to complete the reaction to produce the anti-oxidized thin film with low degree of crystallinity, and to avoid producing the anti-oxidized thin film with high degree of crystallinity.

In some embodiments, after introducing the mixing gas, a stable pressure controlling step is performed for several minutes, such as about 2 minutes to about 3 minutes. In some embodiments, a pressure of the LPCVD process is controlled in a range of about 0.1 Torr and about 100 Torr. The LPCVD process performed with the aforementioned pressure can form the anti-oxidized thin film of the amorphous silicon with high quality. A thickness of the anti-oxidized thin film can be controlled depending on a processing time of the LPCVD process. In some cases, the LPCVD process is performed for 1 hour to 12 hours, and the thickness of the anti-oxidized thin film can be about 50 nm to about 1000 nm.

Since the conventional method is disadvantageous to perform a surface modification for the inner surface of the pipe, especially those pipes with smaller inner diameter, greater aspect ratio and/or irregular shape. For example, it is noted that the pipes with irregular shape can have plural bends, while bending angles thereof are at least partially the same or are different from each other. Therefore, the method of the present invention adopts the LPCVD process and controls the specific reaction parameters, so as to blanketly deposit the anti-oxidized thin film 130 with high homogeneity on the inner surface of the hollow metal pipe 110, and the desired thickness of the thin film can be effectively controlled. Moreover, when the anti-oxidized thin film 130 has the specific low degree of crystallinity or amorphous state, the anti-oxidation effect is better, such that the pipe can be effectively protected and the service life can be prolonged.

The following embodiments are provided to better elucidate the practice of the present invention and should not be interpreted in anyway as to limit the scope of same. Those skilled in the art will recognize that various modifications may be made while not departing from the spirit and scope of the invention. All publication and patent applications mentioned in the specification are indicative of the level of those skilled in the art to which this invention pertains.

### Embodiment 1 and Comparative Example 1

The anti-oxidized metal pipe of embodiment 1 was composed of a hollow pipe including stainless steel and an anti-oxidized thin film including hydrogenated amorphous silicon, while the anti-oxidized thin film was formed by the LPCVD process of the present invention. Comparative example 1 was a hollow pipe of stainless steel without performing any modification treatment. The pipes of embodiment 1 and comparative example 1 were tested, respectively, by sealing the pipes in a test container, while temperature was controlled at 20° C., while the test container was full of oxidant in high concentration (i.e. having the concentration of oxygen about 70% to 95%).

Since oxidation-reduction reaction was continuously occurred in the test container, gases were produced and pressure of the test container was increased constantly. Therefore, a terminal incremental slope can be calculated by a variation in the pressure over time, and the terminal incremental slope can be used to calculate a daily decomposition rate and an equivalent decomposition rate. It was noted that the daily decomposition rate was defined as a ratio of concentration change to test time, while the equivalent decomposition rate was calculated by a surface area of the pipe and oxygen concentration of the test environment based on the daily decomposition rate. Both calculating results were shown in table 1. It should be noted that the test of comparative example 1 only performed for 1 day because the pressure increased too quickly, and the test was ended in advance to avoid hazards.

TABLE 1

| | Environment | | | | equivalent |
|---|---|---|---|---|---|
| | temperature | Test time | terminal incremental | daily decomposition | decomposition rate |
| | (° C.) | (day) | slope (kPa/day) | rate (%/day) | (%/day) |
| Embodiment 1 | 20 | 3 | 151.64 | 0.0134 | 0.00189 |
| Comparative | 20 | 1 | 1782.7 | 1.57 | 0.0222 |
| example 1 | | | | | |

As shown in table 1, the daily decomposition rate and the equivalent decomposition rate of embodiment 1 are both far lower than those of comparative example 1. In other words, the pipe of embodiment 1 with the anti-oxidized thin film can effectively slow down the rate of oxidation of the pipe.

### Embodiment 2 and Comparative Example 2

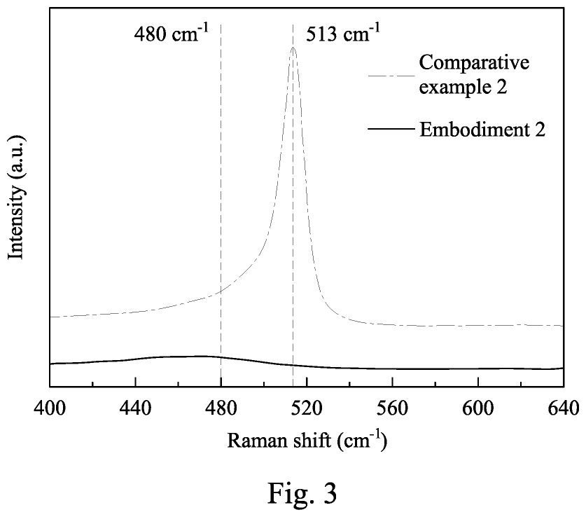

Embodiment 2 and comparative example 2 are similar to embodiment 1, which had the anti-oxidized thin film on the inner surface of the stainless steel pipe. The anti-oxidized thin film of embodiment 2 was amorphous structure, while the anti-oxidized thin film of comparative example 2 included polycrystalline and microcrystalline silicon structure. First, the pipes of embodiment 2 and comparative example 2 were performed Raman spectroscopy test, and the Raman spectrum was shown in FIG. 3. As shown in FIG. 3, the characteristic peak of embodiment 2 was about 480 cm⁻¹, while the characteristic peak of comparative example 2 was about 513 cm⁻¹. According to FIG. 3, the anti-oxidized thin film of embodiment 2 was amorphous structure, while the anti-oxidized thin film of comparative example 2 was polycrystalline and microcrystalline silicon structure with the degree of crystallinity of 75.192%.

Then, the pipes of embodiment 2 and comparative example 2 were deposited in containers with oxidant in high concentration (i.e. having the concentration of oxygen about 70% to 95%). The environment temperature was controlled at 20° C., and reaction was performed for 30 days. After the reaction, the concentration of oxygen in the container was tested to calculate a reaction rate and an oxidation reaction rate of embodiment 2 and comparative example 2, respectively. It was noted that the reaction rate was defined as a ratio of concentration variation to test time, while the oxidation rate was calculated by a surface area of the pipe and oxygen concentration of the test environment based on the reaction rate. Both calculating results were shown in table 2.

TABLE 2

| | Environment | Test time | reaction rate | oxidation reaction |
|---|---|---|---|---|
| | temperature (° C.) | (day) | (%/day) | rate (%/day) |
| Embodiment 2 | 20 | 30 | 0.0036 | 0.00046 |
| Comparative | 20 | 30 | 0.2867 | 0.36385 |
| example 2 | | | | |

According to table 2, the reaction rate and the oxidation reaction rate of embodiment 2 were both lower than those of comparative example 2, in which the oxidation reaction rate difference was about 790 times. In other words, compared to comparative example 2 including polycrystalline and microcrystalline silicon, the anti-oxidized thin film of embodiment 2 including amorphous silicon obviously had better anti-oxidation property.

### Adhesion Test

The pipe of embodiment 1 was performed “paints and varnishes cross-cut test” of ISO2409 and “standard test methods for rating adhesion by tape test” of ASTM D3359. First, grid cuttings were formed on the anti-oxidized thin film on the pipe of embodiment 1, and then the tape was pasted on the cut location. Subsequently, the tape was removed, and removing and damage degrees of the anti-oxidized thin film were evaluated according to defined evaluation criteria. Based on the experiment observation, the anti-oxidized thin film of embodiment 1 was not removed, and it represented that the adhesion evaluated by the cross-cut test was classified as 5B, which was the greatest level.

Additionally, Revetest® Scratch tester was used to perform a scratch adhesion analysis for the pipe of embodiment 1, and the measured adhesion was 6.5 to 11.9N.

### Environmental Durability Test

The anti-oxidation metal pipe of embodiment 2 was performed a neutral salt spray test to evaluate resistance to salt spray corrosion of the metal pipe and the anti-oxidized thin film. The test simulated a corrosive environment by exposing the pipe to neutral salt fog. The test solution was 5% sodium chloride solution (40 g/L to 60 g/L) with pH value of 6.5 to 7.2. The test environment: spray volume of 1 ml to 2 ml (80 cm²/hr), temperature of test room was 351° C., temperature of pressure tank was 471° C., and compressed air pressure was 1.00±0.01 kgf/cm². After the neutral salt spray test for 1500 hours, appearance of the anti-oxidized metal pipe of embodiment 2 showed no significant variation compared to initial appearance. It represented that the anti-oxidized metal pipe with the anti-oxidized thin film had great environmental durability.

According to the above embodiments, the present invention provides the anti-oxidized metal pipe and the method of fabricating the same. The anti-oxidized metal pipe has great anti-oxidized property in the highly oxidizing environment by depositing the anti-oxidized thin film on the inner surface of the hollow metal pipe and controlling the degree of crystallinity of the anti-oxidized thin film, and further the anti-oxidized thin film has excellent adhesion property with the inner surface of the hollow metal pipe.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An anti-oxidized metal pipe, comprising:
a hollow metal pipe, wherein the hollow metal pipe has an inner diameter between 1.0 mm to 4.5 mm; and
an anti-oxidized thin film, blanketly covering an inner surface of the hollow metal pipe, wherein the anti-oxidized thin film has a degree of crystallinity not greater than 40%.

2. The anti-oxidized metal pipe of claim 1, wherein a material of the hollow metal pipe comprises stainless steel, aluminum alloy, copper alloy or combinations thereof.

3. The anti-oxidized metal pipe of claim 1, wherein a thickness of the anti-oxidized thin film is 50 nm to 1000 nm.

4. The anti-oxidized metal pipe of claim 1, wherein the anti-oxidized thin film completely and blanketly covers the hollow metal pipe.

5. The anti-oxidized metal pipe of claim 1, wherein the degree of crystallinity of the anti-oxidized thin film is 1% to 20%.

6. The anti-oxidized metal pipe of claim 1, wherein the anti-oxidized thin film comprises carbon-free hydrogenated amorphous silicon.

7. A method of fabricating an anti-oxidized metal pipe, comprising:
providing a hollow metal pipe into a process chamber; and
performing a low-pressure chemical vapor deposition process in the process chamber to form an anti-oxidized thin film on an inner surface of the hollow metal pipe, wherein the anti-oxidized thin film has a degree of crystallinity not greater than 40%.

8. The method of fabricating the anti-oxidized metal pipe of claim 7, wherein the low-pressure chemical vapor deposition process comprises:
heating the process chamber to a reaction temperature, wherein the reaction temperature is 420° C. to 600° C.; and
introducing a mixing gas comprising silane and hydrogen gas into the process chamber.

9. The method of fabricating the anti-oxidized metal pipe of claim 8, wherein based on a volume of the hydrogen gas as 100 vol %, a volume of the silane is 40 vol % to 60 vol %.

10. The method of fabricating the anti-oxidized metal pipe of claim 7, wherein a pressure of the low-pressure chemical vapor deposition process is 0.1 Torr to 100 Torr.

11. The method of fabricating an anti-oxidized metal pipe of claim 7, wherein before performing the low-pressure chemical vapor deposition process, the method further comprises performing an oxidation process to form a metal oxide layer on the inner surface of the hollow metal pipe.

12. The method of fabricating an anti-oxidized metal pipe of claim 11, wherein the anti-oxidized thin film is covalently bonded to the metal oxide layer.

13. The method of fabricating an anti-oxidized metal pipe of claim 7, wherein the hollow metal pipe has an aspect ratio not smaller than 114.

14. The method of fabricating an anti-oxidized metal pipe of claim 7, wherein the hollow metal pipe has an inner diameter between 1.0 mm to 4.5 mm.

15. An anti-oxidized metal pipe, comprising:
a hollow metal pipe, wherein the hollow metal pipe has an aspect ratio not smaller than 114; and
an anti-oxidized thin film, blanketly covering an inner surface of the hollow metal pipe, wherein the anti-oxidized thin film comprises an amorphous structure.

16. The anti-oxidized metal pipe of claim 15, wherein the hollow metal pipe has an inner diameter between 1.0 mm to 4.5 mm.

17. The anti-oxidized metal pipe of claim 15, wherein the anti-oxidized thin film has a degree of crystallinity not greater than 40%.

18. The anti-oxidized metal pipe of claim 15, wherein a thickness of the anti-oxidized thin film is 50 nm to 1000 nm.

19. The anti-oxidized metal pipe of claim 15, wherein the inner surface of the hollow metal pipe comprises a metal oxide layer.

20. The anti-oxidized metal pipe of claim 19, wherein the anti-oxidized thin film comprises hydrogenated amorphous silicon, and silicon atoms of the hydrogenated amorphous silicon is covalently bonded to oxygen atoms of the metal oxide layer.
